(19) United States
(12) Patent Application Publication
(10) Pub. No.: US 2024/0292535 A1
(43) Pub. Date: Aug. 29, 2024

(54) MULTILAYER BOARD

(71) Applicant: Murata Manufacturing Co., Ltd., Nagaokakyo-shi (JP)

(72) Inventor: Kosuke NISHIO, Nagaokakyo-shi (JP)

(21) Appl. No.: 18/651,724

(22) Filed: May 1, 2024

Related U.S. Application Data
(63) Continuation of application No. PCT/JP2022/042723, filed on Nov. 17, 2022.

(30) Foreign Application Priority Data
Jan. 13, 2022 (JP) 2022-003656

(51) Int. Cl. H05K 1/11; H05K 1/03

(52) U.S. Cl. CPC H05K 1/115; H05K 1/0393; H05K 2201/0141; H05K 2201/015; H05K 2201/096

(57) ABSTRACT

A multilayer board in which interlayer connection conductors include one or more first interlayer connection conductors in a first region and passing through any of a first insulator layer, a second insulator layer, and a third insulator layer in an up-down direction and a second interlayer connection conductor located in a second region and passing through the third insulator layer in the up-down direction. The second interlayer connection conductor is joined to a conductor and a second conductor layer. An area of the second interlayer connection conductor viewed in the up-down direction is larger than a minimum value of areas of the one or more first interlayer connection conductors viewed in the up-down direction.

### CROSS REFERENCE TO RELATED APPLICATIONS

This application claims the benefit of priority to Japanese Patent Application No. 2022-003656 filed on Jan. 13, 2022 and is a Continuation Application of PCT Application No. PCT/JP2022/042723 filed on Nov. 17, 2022. The entire contents of each application are hereby incorporated herein by reference.

### BACKGROUND OF THE INVENTION

### 1. Field of the Invention

The present invention relates to multilayer boards including interlayer connection conductors.

### 2. Description of the Related Art

A flexible board described in Japanese Unexamined Patent Application Publication No. 2002-158445 is known as a multilayer board in the related art. This flexible board has a rigid portion and a flexible portion. The number of laminated layers in the rigid portion is larger than the number of laminated layers in the flexible portion. Thus, the rigid portion is thicker than the flexible portion. Accordingly, the rigid portion is harder to deform than the flexible portion.

In the field of the flexible board described in Japanese Unexamined Patent Application Publication No. 2002-158445, there is a desire to prevent disconnection inside a flexible board.

### SUMMARY OF THE INVENTION

Example embodiments of the present invention provide multilayer boards in each of which disconnection is prevented in a multilayer body.

A multilayer board according to an example embodiment of the present invention includes a multilayer body including a first insulator layer, a second insulator layer, and a third insulator layer laminated in this order in an up-down direction, a first region in which the first insulator layer, the second insulator layer, and the third insulator layer are located when viewed in the up-down direction and a second region in which the first insulator layer and the third insulator layer are located and the second insulator layer is not located when viewed in the up-down direction, each of the first insulator layer and the third insulator layer including a first main surface located in the up-down direction and a second main surface located in the up-down direction, a plurality of interlayer connection conductors in the multilayer body, a conductor in or on the first insulator layer, and a first conductor layer located on the second main surface of the third insulator layer. The plurality of interlayer connection conductors include one or more first interlayer connection conductors located in the first region and passing through any of the first insulator layer, the second insulator layer, and the third insulator layer in the up-down direction and a second interlayer connection conductor located in the second region and passing through the third insulator layer in the up-down direction. The second interlayer connection conductor is joined to the conductor and the first conductor layer. An area of the second interlayer connection conductor viewed in the up-down direction is larger than a minimum value of areas of the one or more first interlayer connection conductors viewed in the up-down direction.

In example embodiments of the present invention, disconnection is prevented in a multilayer body.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a sectional view of a multilayer board 10 according to an example embodiment of the present invention.

FIG. 2 is a sectional view of the multilayer board 10 before thermal pressure bonding.

FIG. 3 is a sectional view of a multilayer board 10a according to an example embodiment of the present invention.

FIG. 4 is a sectional view of the multilayer board 10a before thermal pressure bonding.

FIG. 5 is a sectional view of a multilayer board 10b according to an example embodiment of the present invention.

FIG. 6 is a sectional view of the multilayer board 10b before thermal pressure bonding.

FIG. 7 is a sectional view of a multilayer board 10c according to an example embodiment of the present invention.

FIG. 8 is a sectional view of the multilayer board 10c before thermal pressure bonding.

FIG. 9 is a sectional view of the multilayer board 10c which is bent.

FIG. 10 is a sectional view of a multilayer board 10d according to an example embodiment of the present invention.

FIG. 11 illustrates a sectional view of a multilayer board 10e and a top view of an insulator layer 16e and a conductor layer 18e according to an example embodiment of the present invention.

### DETAILED DESCRIPTION OF THE EXAMPLE EMBODIMENTS

Example embodiments of the present invention will be described in detail below with reference to the drawings.

### Example Embodiment

### Structure of Multilayer Board 10

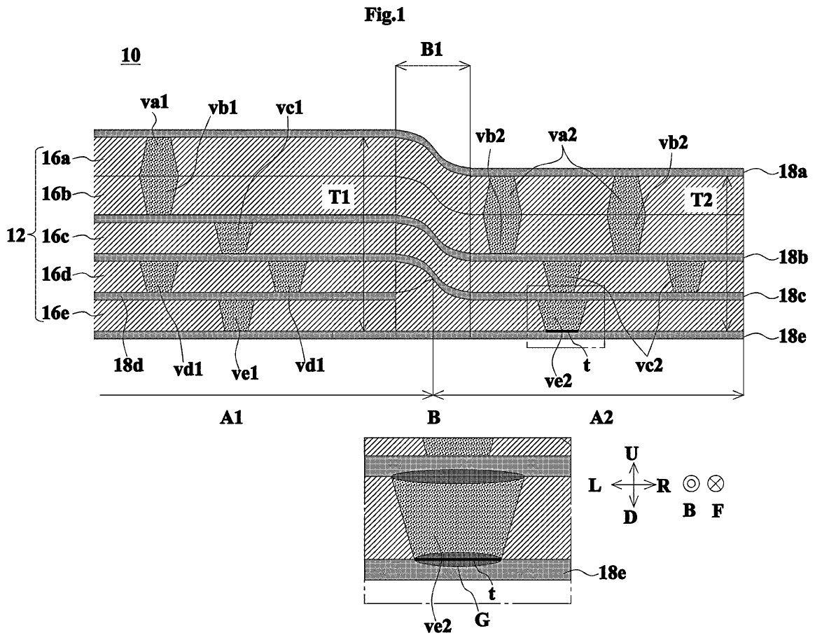

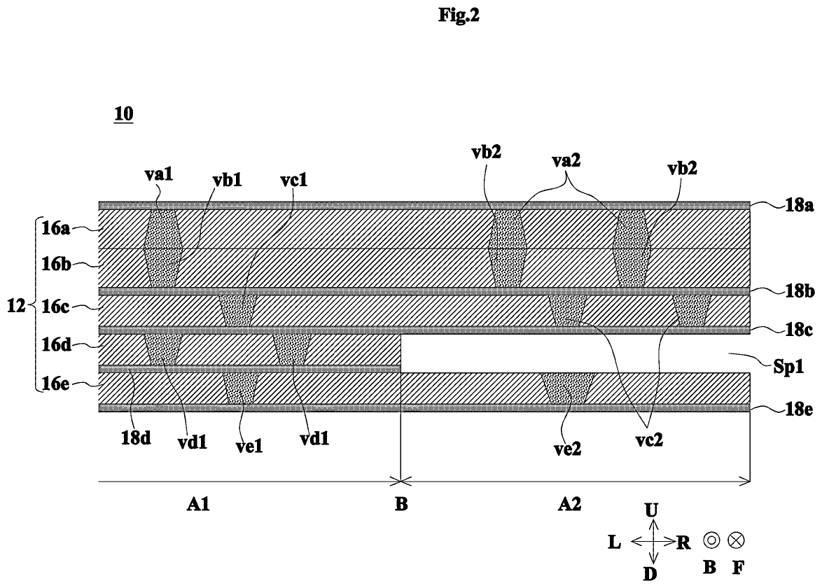

Hereinafter, the structure of a multilayer board 10 according to an example embodiment of the present invention will be described with reference to the drawings. FIG. 1 is a sectional view of the multilayer board 10. FIG. 2 is a sectional view of the multilayer board 10 before thermal pressure bonding.

In the specification, directions are defined as follows. The lamination direction of a multilayer body 12 of the multilayer board 10 is defined as the up-down direction. One direction (the upward direction) of the up-down direction is defined as a first direction. The other direction (the downward direction) of the up-down direction is defined as a second direction. The direction in which a first region A1 and a second region A2 are aligned in FIGS. 1 and 2 is defined as the right-left direction. The direction orthogonal or substantially orthogonal to the up-down direction and the right-left direction is defined as the front-rear direction. The up-down direction, the front-rear direction, and the right-left direction are orthogonal or substantially orthogonal to one another. The up-down direction, the front-rear direction, and the right-left direction in the present specification need not be the same as those of the multilayer board 10 in use.

First, the structure of the multilayer board 10 will be described with reference to FIG. 1. The multilayer board 10 is a flexible board used to electrically connect two circuit boards in an electronic device, such as a smartphone, for example.

As illustrated in FIG. 1, the multilayer board 10 includes the multilayer body 12, conductor layers 18a to 18e, and a plurality of interlayer connection conductors va1, va2, vb1, vb2, vc1, vc2, vd1, ve1, and ve2.

As illustrated in FIG. 1, the multilayer body 12 has a plate shape. Thus, the multilayer body 12 includes upper and lower main surfaces aligned in the up-down direction. The multilayer body 12 is flexible. As illustrated in FIG. 1, the multilayer body 12 has a structure in which insulator layers 16a to 16e (the insulator layer 16c corresponding to a first insulator layer, the insulator layer 16d to a second insulator layer, and the insulator layer 16e to a third insulator layer) are laminated in this order in the downward direction (the second direction). Each of the insulator layers 16a to 16e (the insulator layer 16c corresponding to the first insulator layer, the insulator layer 16d to the second insulator layer, and the insulator layer 16e to the third insulator layer) includes an upper main surface (a first main surface) located in the upward direction (the first direction) and a lower main surface (a second main surface) located in the downward direction (the second direction).

The multilayer body 12 includes the first region A1 and the second region A2. In the first region A1, the insulator layer 16c (the first insulator layer), the insulator layer 16d (the second insulator layer), and the insulator layer 16e (the third insulator layer) are located when viewed in the up-down direction. In the second region A2, the insulator layer 16c (the first insulator layer) and the insulator layer 16e (the third insulator layer) are located, and the insulator layer 16d (the second insulator layer) is not located, when viewed in the up-down direction. In FIG. 1, the first region A1 is located on the left side of the second region A2. The first region A1 and the second region A2 are in contact with each other.

As described above, the insulator layer 16d is provided in the first region A1 and is not provided in the second region A2. Thus, the thickness T1 of the multilayer body 12 in the up-down direction in the first region A1 is larger than the thickness T2 of the multilayer body 12 in the up-down direction in the second region A2. The multilayer body 12 includes a boundary region B1 including the boundary B of the first region A1 and the second region A2. The thickness of the multilayer body 12 in the up-down direction in the boundary region B1 decreases in the direction from the first region A1 to the second region A2 (the right direction). In the boundary region B1, the thickness of the multilayer body 12 in the up-down direction varies continuously.

The insulator layers 16a to 16e are flexible dielectric sheets. The material of the insulator layers 16a to 16e is, for example, a resin. In the present example embodiment, the material of the insulator layers 16a to 16e is, for example, a thermoplastic resin. The material of the insulator layer 16c (the first insulator layer), the material of the insulator layer 16d (the second insulator layer), and the material of the insulator layer 16e (the third insulator layer) are the same thermoplastic resin. Examples of the thermoplastic resin include, for example, a liquid crystal polymer and polytetrafluoroethylene (PTFE). The material of the insulator layers 16a to 16e may be, for example, polyimide. In the insulator layers 16a to 16e, layers adjacent in the up-down direction are fusion-bonded.

The conductor layers 18a to 18e are located in or on the multilayer body 12. Each of the conductor layers 18a to 18e (a first conductor layer and a second conductor layer) includes an upper main surface (a third main surface) located in the upward direction (the first direction) and a lower main surface (a fourth main surface) located in the downward direction (the second direction). More specifically, the conductor layer 18a is located on the upper main surface of the insulator layer 16a. The surface roughness of the lower main surface of the conductor layer 18a is larger than that of the upper main surface of the conductor layer 18a. This causes the conductor layer 18a to be bonded to the insulator layer 16a. The conductor layer 18b is located on the lower main surface of the insulator layer 16b. The surface roughness of the upper main surface of the conductor layer 18b is larger than that of the lower main surface of the conductor layer 18b. This causes the conductor layer 18b to be bonded to the insulator layer 16b. The conductor layer 18b is also bonded to the insulator layer 16c. However, the strength of the conductor layer 18b bonding to the insulator layer 16b is larger than the strength of the conductor layer 18b bonding to the insulator layer 16c. The conductor layer 18c (a conductor) is located on the insulator layer 16c (the first insulator layer). More specifically, the conductor layer 18c (the second conductor layer) is located on the lower main surface (the second main surface) of the insulator layer 16c (the first insulator layer). The surface roughness of the upper main surface (the third main surface) of the conductor layer 18c (the second conductor layer) is larger than that of the lower main surface (the fourth main surface) of the conductor layer 18c (the second conductor layer). This causes the conductor layer 18c to be bonded to the insulator layer 16c. The conductor layer 18c is also bonded to the insulator layers 16d and 16e. However, the strength of the conductor layer 18c bonding to the insulator layer 16c is larger than the strength of the conductor layer 18c bonding to the insulator layers 16d and 16e. The conductor layer 18d is located on the lower main surface of the insulator layer 16d. The surface roughness of the upper main surface of the conductor layer 18d is larger than that of the lower main surface of the conductor layer 18d. This causes the conductor layer 18d to be bonded to the insulator layer 16d. The conductor layer 18d is also bonded to the insulator layer 16e. However, the strength of the conductor layer 18d bonding to the insulator layer 16d is larger than the strength of the conductor layer 18d bonding to the insulator layer 16e. The conductor layer 18e (the first conductor layer) is located on the lower main surface (the fourth main surface) of the insulator layer 16e (the third insulator layer). The surface roughness of the upper main surface (the third main surface) of the conductor layer 18e (the first conductor layer) is larger than that of the lower main surface (the fourth main surface) of the conductor layer 18e (the first conductor layer). This causes the conductor layer 18e to be bonded to the insulator layer 16e.

The conductor layers 18a to 18c and 18e described above are located in both the first region A1 and the second region A2. The conductor layer 18d is located in the first region A1 and not in the second region A2. The conductor layers 18a to 18e include a signal line, a ground line, a ground conductor, a power line, a floating conductor, a signal electrode, and a ground electrode. The material of the conductor layers 18a to 18e described above is a metal. The material of the conductor layers 18a to 18e is, for example, copper.

The plurality of interlayer connection conductors va1, va2, vb1, vb2, vc1, vc2, vd1, ve1, and ve2 are provided in the multilayer body 12. The interlayer connection conductor va1 is located in the first region A1 and passes through the insulator layer 16a in the up-down direction. The interlayer connection conductors va2, the number of which is two, are located in the second region A2 and pass through the insulator layer 16a in the up-down direction. The interlayer connection conductor vb1 is located in the first region A1 and passes through the insulator layer 16b in the up-down direction. The interlayer connection conductors vb2, the number of which is two, are located in the second region A2 and pass through the insulator layer 16b in the up-down direction. The interlayer connection conductor vc1 (a first interlayer connection conductor) is located in the first region A1 and passes through the insulator layer 16c (the first insulator layer) in the up-down direction. The interlayer connection conductors vc2 (fourth interlayer connection conductors), the number of which is two, are located in the second region A2 and pass through the insulator layer 16c (the first insulator layer) in the up-down direction. The interlayer connection conductors vd1 (first interlayer connection conductors), the number of which is two, are located in the first region A1 and pass through the insulator layer 16d (the second insulator layer) in the up-down direction. The interlayer connection conductor ve1 (a first interlayer connection conductor, a third interlayer connection conductor) is located in the first region A1 and passes through the insulator layer 16e (the third insulator layer) in the up-down direction. The interlayer connection conductor ve2 (a second interlayer connection conductor) is located in the second region A2 and passes through the insulator layer 16e (the third insulator layer) in the up-down direction.

The interlayer connection conductor va1 is joined to the conductor layer 18a and the interlayer connection conductor vb1. The interlayer connection conductors va2 are joined to the conductor layer 18a and the interlayer connection conductors vb2. The interlayer connection conductor vb1 is joined to the conductor layer 18b and the interlayer connection conductor va1. The interlayer connection conductors vb2 are joined to the conductor layer 18b and the interlayer connection conductors va2. The interlayer connection conductor vc1 is joined to the conductor layer 18b and the conductor layer 18c. The interlayer connection conductors vc2 (the fourth interlayer connection conductors) are joined to the conductor layer 18b and the conductor layer 18c (the second conductor layer). The interlayer connection conductors vd1 are joined to the conductor layer 18c and the conductor layer 18d. The interlayer connection conductor ve1 (the third interlayer connection conductor) is joined to the conductor layer 18d and the conductor layer 18e. The interlayer connection conductor ve2 (the second interlayer connection conductor) is joined to the conductor layer 18c (the conductor, the second conductor layer) and the conductor layer 18e (the first conductor layer).

The plurality of interlayer connection conductors va1, va2, vb1, vb2, vc1, vc2, vd1, ve1, and ve2 described above are formed by, for example, filling through holes extending through the insulator layers 16a to 16e in the up-down direction with a conductive paste and applying a heating and pressing process to solidify the conductive paste. The conductive paste is a mixture of a resin and a metal, for example. The plurality of solidified interlayer connection conductors va1, va2, vb1, vb2, vc1, vc2, vd1, ve1, and ve2 include the metal and the remaining resin. As described above, the plurality of interlayer connection conductors va1, va2, vb1, vb2, vc1, vc2, vd1, ve1, and ve2 are produced with the same kind of material. Thus, the material of the interlayer connection conductor ve2 (the second interlayer connection conductor) and the material of the interlayer connection conductors va1, vb1, vc1, vd1, and ve1 (the first interlayer connection conductors) are of the same kind.

The plurality of interlayer connection conductors va1, va2, vb1, vb2, vc1, vc2, vd1, ve1, and ve2 have truncated cone shapes. Each of the interlayer connection conductors va1 and va2 becomes thicker from top to bottom. Each of the interlayer connection conductors vb1, vb2, vc1, vc2, vd1, ve1, and ve2 becomes thicker from bottom to top. In the present specification, an interlayer connection conductor becoming thicker denotes the sectional area of the interlayer connection conductor in the directions orthogonal or substantially orthogonal to the up-down direction increasing.

The area of the interlayer connection conductor ve2 (the second interlayer connection conductor) viewed in the up-down direction is larger than the minimum value of the areas of the interlayer connection conductors va1, vb1, vc1, vd1, and ve1 (the first interlayer connection conductors) viewed in the up-down direction. The interlayer connection conductors va1, vb1, vc1, vd1, and ve1 are located in the first region A1. A description will be provided below of the area of an interlayer connection conductor in the present specification. The following is based on an example of the interlayer connection conductor ve2. As described above, the interlayer connection conductor ve2 has a truncated cone shape. The area of the interlayer connection conductor ve2 viewed in the up-down direction refers to the area of the narrower end t of the upper and lower ends of the interlayer connection conductor ve2 viewed in the up-down direction. The narrower end t of the upper and lower ends of the interlayer connection conductor ve2 is in contact with the conductor layer 18e. The material of the interlayer connection conductor ve2 differs from the material of the conductor layer 18e. Thus, it is relatively easy to determine the boundary between the interlayer connection conductor ve2 and the conductor layer 18e. The boundary between the interlayer connection conductor ve2 and the conductor layer 18e corresponds to the narrower end t of the upper and lower ends of the interlayer connection conductor ve2. However, an alloy layer G including an alloy of the material of the conductor layer 18e and the interlayer connection conductor ve2 is provided at the boundary between the conductor layer 18e and the interlayer connection conductor ve2. The end t is a portion in the alloy layer G, flush with the upper main surface of the conductor layer 18e.

In the multilayer board 10, the area of the interlayer connection conductor ve2 (the second interlayer connection conductor) viewed in the up-down direction is larger than the area of the interlayer connection conductor ve1 (the third interlayer connection conductor) viewed in the up-down direction. The interlayer connection conductor ve1 is located in the insulator layer 16e which is the same insulator layer where the interlayer connection conductor ve2 is located.

In the multilayer board 10, the area of the interlayer connection conductor ve2 (the second interlayer connection conductor) viewed in the up-down direction is larger than the maximum value of the areas of the interlayer connection conductors va1, vb1, vc1, vd1, and ve1 (the first interlayer connection conductors) viewed in the up-down direction. In addition, in the multilayer board 10, the area of the interlayer connection conductor ve2 (the second interlayer connection conductor) viewed in the up-down direction is larger than the area of each of the interlayer connection conductors vc2 (the fourth interlayer connection conductors) viewed in the up-down direction.

### Advantageous Effects

In the multilayer board 10, the occurrence of disconnection is prevented in the multilayer body 12. More specifically, as illustrated in FIG. 2, the insulator layer 16d is located in the first region A1, and the insulator layer 16d not in the second region A2. With this configuration, in the multilayer body 12 before a thermal pressure bonding process, a space Sp1 is provided between the insulator layer 16c and the insulator layer 16e in the first region A2. The upper end of the interlayer connection conductor ve2 is exposed to the space Sp1. Then, in the thermal pressure bonding process for the multilayer body 12, the insulator layer 16c and the insulator layer 16e are fusion-bonded in the second region A2 and the space Sp1 disappears. In this process, the interlayer connection conductor ve2 (the second interlayer connection conductor) is joined to the conductor layer 18c (the conductor, the second conductor layer). Since the space Sp1 is provided before the thermal pressure bonding process as described above, it is possible for disconnection to occur between the interlayer connection conductor ve2 (the second interlayer connection conductor) and the conductor layer 18c (the conductor, the second conductor layer).

To address this, the area of the interlayer connection conductor ve2 (the second interlayer connection conductor) viewed in the up-down direction is larger than the minimum value of the areas of the interlayer connection conductors va1, vb1, vc1, vd1, and ve1 (the first interlayer connection conductors) viewed in the up-down direction. For example, if the area of the interlayer connection conductor va1 viewed in the up-down direction is the smallest among the areas of the interlayer connection conductors va1, vb1, vc1, vd1, and ve1 viewed in the up-down direction, the area of the interlayer connection conductor ve2 (the second interlayer connection conductor) viewed in the up-down direction is larger than the area of the interlayer connection conductor va1 viewed in the up-down direction. As described above, in the case in which the area of the interlayer connection conductor ve2 (the second interlayer connection conductor) viewed in the up-down direction is large, the area of contact between the interlayer connection conductor ve2 (the second interlayer connection conductor) and the conductor layer 18c (the conductor, the second conductor layer) is large. Accordingly, the possibility of the occurrence of disconnection between the interlayer connection conductor ve2 (the second interlayer connection conductor) and the conductor layer 18c (the conductor, the second conductor layer) is low. Hence, in the multilayer board 10, the occurrence of disconnection can be prevented in the multilayer body 12.

In the multilayer board 10, the area of the interlayer connection conductor ve2 (the second interlayer connection conductor) viewed in the up-down direction is larger than the area of the interlayer connection conductor ve1 (the third interlayer connection conductor) viewed in the up-down direction. This configuration makes the area of contact between the interlayer connection conductor ve2 (the second interlayer connection conductor) and the conductor layer 18c (the second conductor layer) larger. Accordingly, the possibility of the occurrence of disconnection between the interlayer connection conductor ve2 (the second interlayer connection conductor) and the conductor layer 18c (the second conductor layer) is even lower. In addition, this makes it possible to arrange interlayer connection conductors at necessary positions with narrow pitches, thus increasing the degree of freedom in designing the multilayer board 10.

In the multilayer board 10, the area of the interlayer connection conductor ve2 (the second interlayer connection conductor) viewed in the up-down direction is larger than the maximum value of the areas of the interlayer connection conductors va1, vb1, vc1, vd1, and ve1 (the first interlayer connection conductors) viewed in the up-down direction. For example, if the area of the interlayer connection conductor vb1 viewed in the up-down direction is the largest among the areas of the interlayer connection conductors va1, vb1, vc1, vd1, and ve1 viewed in the up-down direction, the area of the interlayer connection conductor ve2 (the second interlayer connection conductor) viewed in the up-down direction is larger than the area of the interlayer connection conductor vb1 viewed in the up-down direction. This configuration makes the area of contact between the interlayer connection conductor ve2 (the second interlayer connection conductor) and the conductor layer 18c (the second conductor layer) much larger. Accordingly, the possibility of the occurrence of disconnection between the interlayer connection conductor ve2 (the second interlayer connection conductor) and the conductor layer 18c (the second conductor layer) is much lower.

In the multilayer board 10, the area of the interlayer connection conductor ve2 (the second interlayer connection conductor) viewed in the up-down direction is larger than the area of each of the interlayer connection conductors vc2 (the fourth interlayer connection conductors) viewed in the up-down direction. This configuration makes the area of contact between the interlayer connection conductor ve2 (the second interlayer connection conductor) and the conductor layer 18c (the second conductor layer) even larger. Accordingly, the possibility of the occurrence of disconnection between the interlayer connection conductor ve2 (the second interlayer connection conductor) and the conductor layer 18c (the second conductor layer) is even lower.

In the multilayer board 10, the interlayer connection conductor ve2 is joined to the conductor layer 18c. In this configuration, the interlayer connection conductor ve2 is joined to the planar conductor layer 18c. Thus, the occurrence of disconnection is prevented in the multilayer board 10.

In the multilayer board 10, the interlayer connection conductors vc2 are joined to the conductor layer 18c. The area of the interlayer connection conductor ve2 viewed in the up-down direction is larger than the area of each of the interlayer connection conductors vc2 viewed in the up-down direction. This makes it possible to arrange interlayer connection conductors at narrow pitches as necessary also in the second region A2.

### First Modified Example

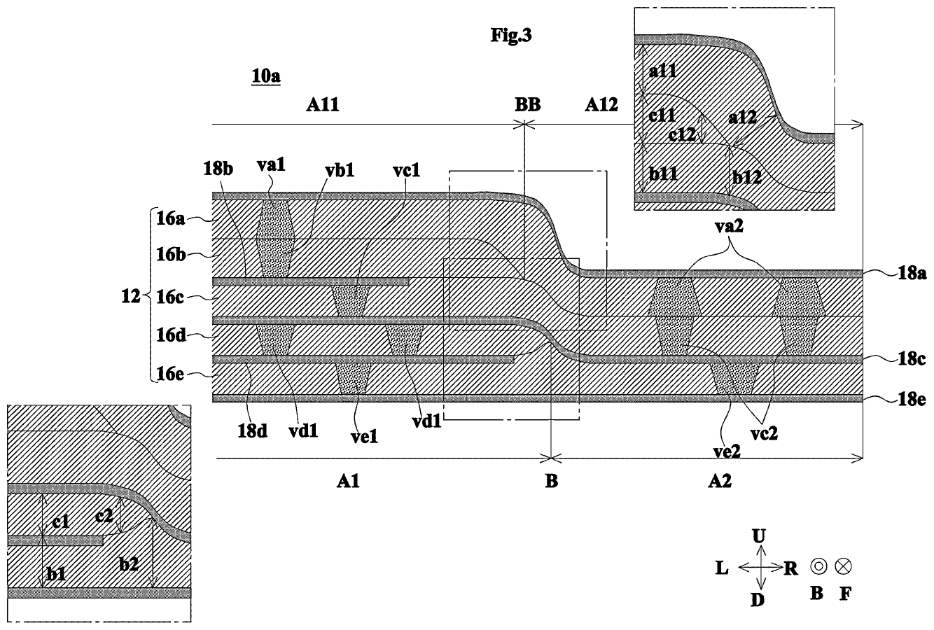

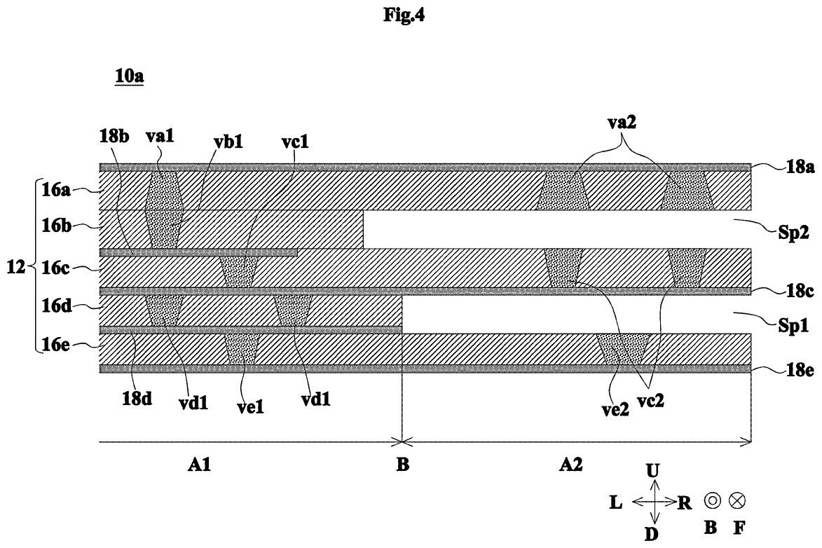

A multilayer board 10a according to a first modified example of a preferred embodiment of the present invention will be described below with reference to the drawings. FIG. 3 is a sectional view of the multilayer board 10a. FIG. 4 is a sectional view of the multilayer board 10a before thermal pressure bonding.

The multilayer board 10a includes the structure of an example embodiment of the present invention at two places. Specifically, in the lower half of the multilayer board 10a, an interlayer connection conductor ve2 corresponds to the second interlayer connection conductor. In the upper half of the multilayer board 10a, interlayer connection conductors va2 correspond to second interlayer connection conductors. A description will be given below.

The multilayer board 10a differs from the multilayer board 10 in the following respects. The first difference relates to the lower half structure of the multilayer board 10a.

The multilayer board 10a has a structure in which insulator layers 16a to 16e (the insulator layer 16c corresponding to the first insulator layer, the insulator layer 16d to the second insulator layer, the insulator layer 16e to the third insulator layer, the insulator layer 16b to a fourth insulator layer, and the insulator layer 16a to a fifth insulator layer) are laminated in this order in the downward direction (the second direction).

The insulator layer 16a (the fifth insulator layer) is located in the first region A1 and the second region A2.

The insulator layer 16b (the fourth insulator layer) is located in the first region A1 and is not in contact with the boundary B between the first region A1 and the second region A2. In other words, the insulator layer 16b is not located in the second region A2. The distance between the insulator layer 16b and the boundary B is, for example, larger than or equal to the thickness of the insulator layer 16b in the up-down direction.

With the differences described above, the insulator layer 16a and the insulator layer 16c are fusion-bonded in the second region A2 and a portion of the first region A1.

The multilayer board 10a also differs from the multilayer board 10 in the following respects. The differences relate to the upper half structure of the multilayer board 10a.

The multilayer body 12 includes a first region A11 and a second region A12. In the first region A11, the insulator layer 16c (the first insulator layer), the insulator layer 16b (the second insulator layer), and the insulator layer 16a (the third insulator layer) are located when viewed in the up-down direction. In the second region A12, the insulator layer 16c (the first insulator layer) and the insulator layer 16a (the third insulator layer) are located, and the insulator layer 16b (the second insulator layer) is not located, when viewed in the up-down direction.

The interlayer connection conductors va2 (the second interlayer connection conductors), the number of which is two, are located in the second region A12 and pass through the insulator layer 16a (the third insulator layer) in the up-down direction.

Two interlayer connection conductors vc2 (the fourth interlayer connection conductors, conductors) are located in the insulator layer 16c (the first insulator layer). More specifically, the two interlayer connection conductors vc2 (the fourth interlayer connection conductors) are located in the second region A12 and pass through the insulator layer 16c (the first insulator layer) in the up-down direction.

The interlayer connection conductors va2 (the second interlayer connection conductors) are joined to the interlayer connection conductors vc2 (the conductors, the fourth interlayer connection conductors).

The area of each of the two interlayer connection conductors va2 (the second interlayer connection conductors) viewed in the up-down direction is larger than the area of each of the interlayer connection conductors vc2 (the fourth interlayer connection conductors) viewed in the up-down direction.

The multilayer board 10a satisfies the following conditions.

The thickness b2 of the insulator layer 16e (the third insulator layer) in the up-down direction at the boundary B between the first region A1 and the second region A2 is larger than the thickness b1 of the insulator layer 16e (the third insulator layer) in the up-down direction in the first region A1.

The thickness of the insulator layer 16d (the second insulator layer) in the up-down direction decreases toward the boundary B between the first region A1 and the second region A2, i.e., c1>c2.

In addition, the multilayer board 10a satisfies the following conditions.

The thickness a12 of the insulator layer 16a in the up-down direction at the boundary BB between the first region A11 and the second region A12 is larger than the thickness a11 of the insulator layer 16a in the up-down direction in the first region A11.

The thickness b12 of the insulator layer 16c in the up-down direction at the boundary BB between the first region A11 and the second region A12 is larger than the thickness b11 of the insulator layer 16c in the up-down direction in the first region A11.

The thickness of the insulator layer 16b in the up-down direction decreases toward the boundary BB between the first region A11 and the second region A12, i.e., c11>c12.

The rest of the structure of the multilayer board 10a is the same or substantially the same as that of the multilayer board 10. In the multilayer board 10a, the insulator layer 16b (the fourth insulator layer) is located in the first region A1 and is not in contact with the boundary B between the first region A1 and the second region A2. Thus, the right end of the insulator layer 16b is not aligned with the right end of the insulator layer 16d in the up-down direction. This configuration prevents an abrupt change in the thickness of the multilayer body 12 in the up-down direction at or near the boundary B between the first region A1 and the second region A2. This in turn prevents the insulator layer 16a from peeling off the insulator layer 16b.

In the multilayer board 10a, the area of each of the two interlayer connection conductors va2 (the second interlayer connection conductors) viewed in the up-down direction is larger than the minimum value of the areas of the interlayer connection conductors va1, vb1, vc1, vd1, and ve1 (the first interlayer connection conductors) viewed in the up-down direction and larger than the area of each of the interlayer connection conductors vc2 (the fourth interlayer connection conductors) viewed in the up-down direction. This configuration makes the area of each of the two interlayer connection conductors va2 (the second interlayer connection conductors) viewed in the up-down direction large and also makes the area of contact between the interlayer connection conductors va2 (the second interlayer connection conductors) and the interlayer connection conductors vc2 (the fourth interlayer connection conductors) large. Accordingly, the possibility of the occurrence of disconnection between the interlayer connection conductor va2 (the second interlayer connection conductor) and the interlayer connection conductors vc2 (the fourth interlayer connection conductors) is low.

The area of each of the interlayer connection conductors ve2 (the second interlayer connection conductors) viewed in the up-down direction may be larger than the minimum value of the areas of the interlayer connection conductors va1, vb1, vc1, vd1, and ve1 (the first interlayer connection conductors) viewed in the up-down direction and larger than the area of each of the interlayer connection conductors vc2 (the fourth interlayer connection conductors) viewed in the up-down direction. In addition, the structure of the multilayer board 10 may be applied to the multilayer board 10a.

### Second Modified Example

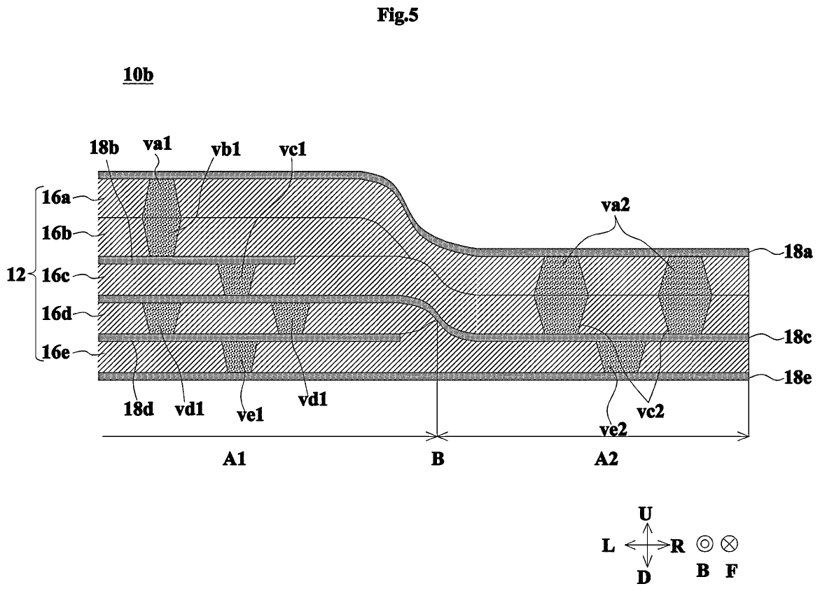

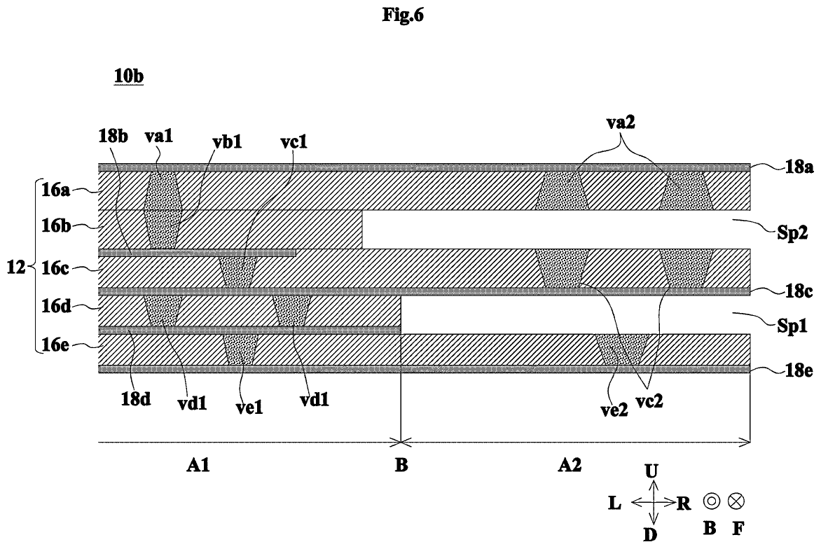

A multilayer board 10b according to a second modified example of an example embodiment of the present invention will be described below with reference to the drawings. FIG. 5 is a sectional view of the multilayer board 10b. FIG. 6 is a sectional view of the multilayer board 10b before thermal pressure bonding.

The multilayer board 10b differs from the multilayer board 10a in that the area of each of two interlayer connection conductors va2 (the second interlayer connection conductors) viewed in the up-down direction is equal or substantially equal to the area of each of two interlayer connection conductors vc2 (the fourth interlayer connection conductors) viewed in the up-down direction. The rest of the structure of the multilayer board 10b is the same or substantially the same as that of the multilayer board 10a, and thus description thereof is omitted. In the multilayer board 10b, the area of contact between the interlayer connection conductors va2 (the second interlayer connection conductors) and the interlayer connection conductors vc2 (the fourth interlayer connection conductors) is larger. Accordingly, the possibility of the occurrence of disconnection between the interlayer connection conductor va2 the second interlayer connection conductor) and the interlayer connection conductors vc2 (the fourth interlayer connection conductors) is even lower.

### Third Modified Example

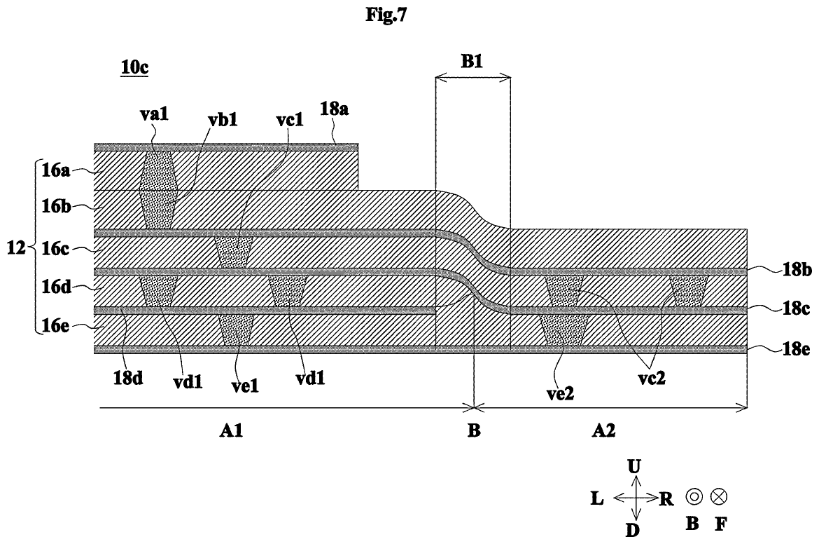

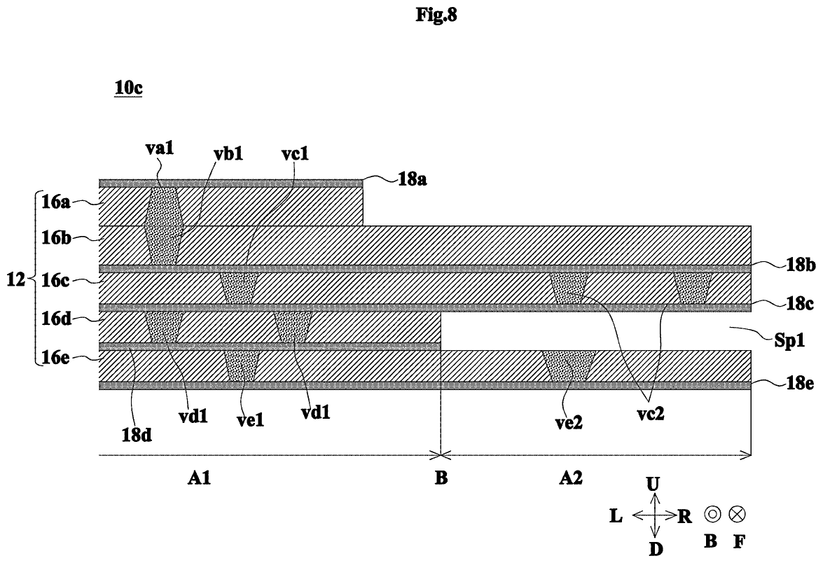

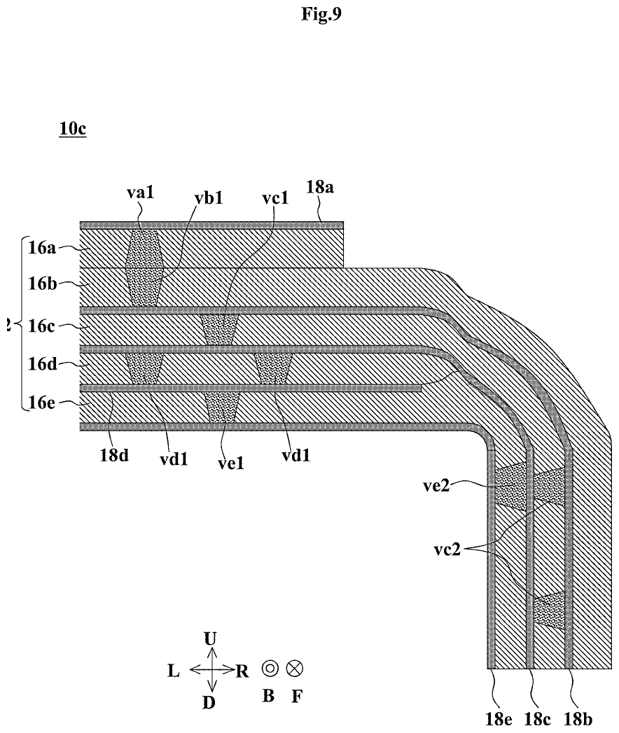

A multilayer board 10c according to a third modified example of an example embodiment of the present invention will be described below with reference to the drawings. FIG. 7 is a sectional view of the multilayer board 10c. FIG. 8 is a sectional view of the multilayer board 10c before thermal pressure bonding. FIG. 9 is a sectional view of the multilayer board 10c which is bent.

The multilayer board 10c differs from the multilayer board 10 in the following points.

The multilayer board 10c has a structure in which insulator layers 16a to 16e (the insulator layer 16c corresponding to the first insulator layer, the insulator layer 16d to the second insulator layer, the insulator layer 16e to the third insulator layer, and the insulator layer 16a to the fourth insulator layer) are laminated in this order in the downward direction (the second direction).

The insulator layer 16a (the fourth insulator layer) is located in the first region A1 and is not in contact with the boundary B between the first region A1 and the second region A2. In other words, the insulator layer 16a is not located in the second region A2. The distance between the insulator layer 16a and the boundary B is, for example, larger than or equal to the thickness of the insulator layer 16a in the up-down direction.

The rest of the structure of the multilayer board 10c is the same or substantially the same as that of the multilayer board 10, and thus description thereof is omitted. In the multilayer board, the insulator layer 16a (the fourth insulator layer) is located in the first region A1 and is not in contact with the boundary B between the first region A1 and the second region A2. Thus, the right end of the insulator layer 16a is not aligned with the right end of the insulator layer 16d in the up-down direction. This configuration prevents an abrupt change in the thickness of the multilayer body 12 in the up-down direction at or near the boundary B between the first region A1 and the second region A2. This in turn prevents the insulator layer 16a from peeling off the insulator layer 16b.

In the multilayer board 10c, the insulator layer 16a (the fourth insulator layer) is located in the first region A1 and is not in contact with the boundary B between the first region A1 and the second region A2. As illustrated in FIG. 9, when the multilayer board 10b is bent, the insulator layer 16a is less likely to deform. Thus, the insulator layer 16a is less likely to peel off the insulator layer 16b.

### Fourth Modified Example

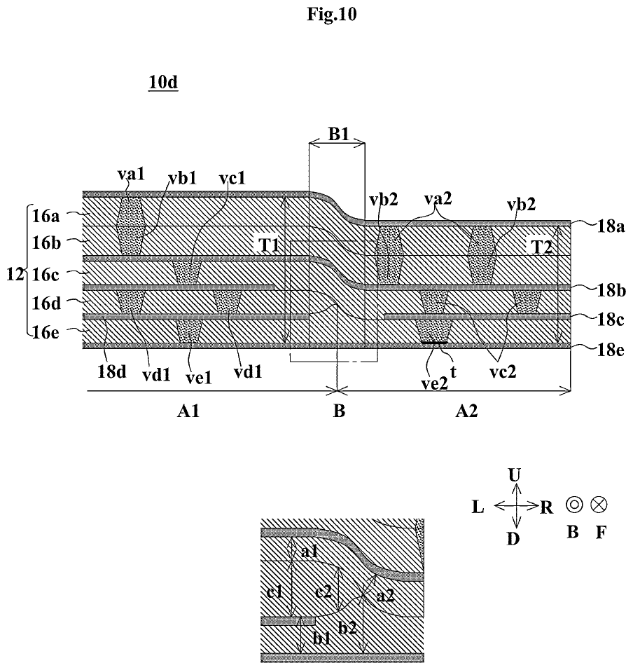

A multilayer board 10d according to a fourth modified example of an example embodiment of the present invention will be described below with reference to the drawings. FIG. 10 is a sectional view of the multilayer board 10d.

The multilayer board 10d differs from the multilayer board 10 in that the conductor layer 18c is not located at or near the boundary B. The multilayer board 10d may satisfy the following conditions.

The thickness a2 of the insulator layer 16c (the first insulator layer) in the up-down direction at the boundary B between the first region A1 and the second region A2 is larger than the thickness a1 of the insulator layer 16c (the first insulator layer) in the up-down direction in the first region A1.

The thickness b2 of the insulator layer 16e (the third insulator layer) in the up-down direction at the boundary B between the first region A1 and the second region A2 is larger than the thickness b1 of the insulator layer 16e (the third insulator layer) in the up-down direction in the first region A1.

The thickness of the insulator layer 16d (the second insulator layer) in the up-down direction decreases toward the boundary B between the first region A1 and the second region A2, i.e., c1>c2.

The rest of the structure of the multilayer board 10d is the same or substantially the same as that of the multilayer board 10. In the multilayer board 10d, the above structure enables the insulator layer 16c and the insulator layer 16e to be fusion-bonded firmly at the boundary B between the first region A1 and the second region A2. Thus, the occurrence of peeling in the insulator layers 16c, 16d, and 16e is prevented.

### Fifth Modified Example

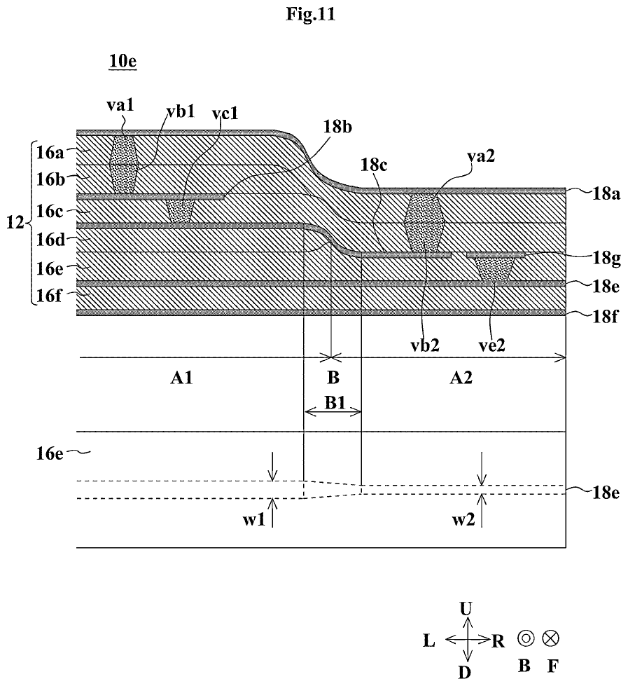

A multilayer board 10e according to a fifth modified example of an example embodiment of the invention will be described below with reference to the drawings. FIG. 11 illustrates a sectional view of the multilayer board 10e and a top view of an insulator layer 16e and a conductor layer 18e.

The multilayer board 10e differs from the multilayer board 10a in the following points.

The conductor layer 18e (the first conductor layer) has a linear shape when viewed in the up-down direction. Specifically, the conductor layer 18e is a signal conductor layer used to transmit a high-frequency signal.

The multilayer body 12 further includes an insulator layer 16f laminated under the insulator layer 16e.

The multilayer board 10e further includes a conductor layer 18f located on the lower main surface of the insulator layer 16f.

The multilayer board 10e further includes a conductor layer 18g located on the lower main surface of the insulator layer 16c.

The multilayer board 10e does not include the conductor layer 18d.

The conductor layers 18c and 18f are ground conductor layers connected to the ground potential.

The conductor layer 18g is a signal conductor layer.

An interlayer connection conductor ve2 is joined to the conductor layer 18e and the conductor layer 18g.

The line width w1 of the conductor layer 18e (the first conductor layer) viewed in the up-down direction in the first region A1 is larger than the line width w2 of the conductor layer 18e (the first conductor layer) viewed in the up-down direction in the second region A2.

The line width of the conductor layer 18e (the first conductor layer) viewed in the up-down direction in the boundary region B1 decreases in the direction from the first region A1 to the second region A2 (the right direction).

The rest of the structure of the multilayer board 10e is the same or substantially the same as that of the multilayer board 10a, and thus description thereof is omitted. The multilayer board 10e makes it possible to prevent the characteristic impedance of the conductor layer 18e from deviating from a specified characteristic impedance (for example, 50 Ω). More specifically, the distance between the conductor layer 18c, which is a ground conductor layer, and the conductor layer 18e, which is a signal conductor layer, in the first region A1 is larger than the distance between the conductor layer 18c, which is a ground conductor layer, and the conductor layer 18e, which is a signal conductor layer, in the second region A2. Thus, the capacitance between the conductor layer 18c and the conductor layer 18e in the first region A1 is likely to be smaller than the capacitance between the conductor layer 18c and the conductor layer 18e in the second region A2. Thus the characteristic impedance of the conductor layer 18e in the first region A1 is likely to be higher than the characteristic impedance of the conductor layer 18e in the second region A2.

To address this, in the multilayer board 10e, the line width w1 of the conductor layer 18e (the first conductor layer) viewed in the up-down direction in the first region A1 is larger than the line width w2 of the conductor layer 18e (the first conductor layer) viewed in the up-down direction in the second region A2. This makes the capacitance between the conductor layer 18c and the conductor layer 18e in the first region A1 close to the capacitance between the conductor layer 18c and the conductor layer 18e in the second region A2. Thus, the characteristic impedance of the conductor layer 18e in the first region A1 is close to the characteristic impedance of the conductor layer 18e in the second region A2. Thus, the multilayer board 10e makes it possible to prevent the characteristic impedance of the conductor layer 18e from deviating from a specified characteristic impedance (for example, 50 Ω).

In the boundary region B1, the distance between the conductor layer 18c and the conductor layer 18e decreases in the direction from the first region A1 to the second region A2 (the right direction). Accordingly, the line width of the conductor layer 18e (the first conductor layer) viewed in the up-down direction in the boundary region B1 decreases in the direction from the first region A1 to the second region A2 (the right direction). This configuration makes it possible to prevent the characteristic impedance of the conductor layer 18e from varying in the boundary region B1. Thus, the multilayer board 10e makes it possible to prevent the characteristic impedance of the conductor layer 18e from deviating from a specified characteristic impedance (for example, 50 Ω).

### Other Example Embodiments

The multilayer board according to the present invention is not limited to the multilayer boards 10 and 10a to 10e according to example embodiments of the present invention and modifications thereof, and may be changed within the scope of the present invention. The structures of the multilayer boards 10 and 10a to 10e may be combined in any manner.

The numbers of the respective interlayer connection conductors va1, va2, vb1, vb2, vc1, vc2, vd1, ve1, and ve2 may be one or more.

A configuration in which the area of the interlayer connection conductor ve2 (the second interlayer connection conductor) viewed in the up-down direction is smaller than or equal to the area of the interlayer connection conductor ve1 (the third interlayer connection conductor) viewed in the up-down direction is also possible.

A configuration in which the area of the interlayer connection conductor ve2 (the second interlayer connection conductor) viewed in the up-down direction is smaller than or equal to the maximum value of the areas of the interlayer connection conductors va1, vb1, vc1, vd1, and ve1 (the first interlayer connection conductors) viewed in the up-down direction is also possible.

The areas of the interlayer connection conductors va1, vb1, vc1, vd1, and ve1 (the first interlayer connection conductors) viewed in the up-down direction need not be uniform.

The conductor layer 18c may not be provided.

The insulator layers 16a and 16b may not be provided.

The multilayer body 12 may further include an additional interlayer connection conductor other than the interlayer connection conductors va1, va2, vb1, vb2, vc1, vc2, vd1, ve1, and ve2. The material of the additional interlayer connection conductor need not be of the same kind as that of the interlayer connection conductors va1, va2, vb1, vb2, vc1, vc2, vd1, ve1, and ve2. In this case, the additional interlayer connection conductor may be formed, for example, by metal plating the inner peripheral surface of a through hole formed in an insulator layer.

The interlayer connection conductors va1, va2, vb1, vb2, vc1, vc2, vd1, ve1, and ve2 may include, for example, a portion formed by metal plating the inner peripheral surface of a through hole formed in an insulator layer.

The shapes of the plurality of interlayer connection conductors va1, va2, vb1, vb2, vc1, vc2, vd1, ve1, and ve2 are not limited to truncated cone shapes. The shapes of the interlayer connection conductors va1, va2, vb1, vb2, vc1, vc2, vd1, ve1, and ve2 may be, for example, truncated pyramid shapes or plate shapes. However, the heights of the plurality of interlayer connection conductors va1, va2, vb1, vb2, vc1, vc2, vd1, ve1, and ve2 in the up-down direction are, for example, about 0.1 times or more and about 2 times or less the maximum diameter among those of the plurality of interlayer connection conductors va1, va2, vb1, vb2, vc1, vc2, vd1, ve1, and ve2.

The multilayer body 12 may include at least one of a protective layer covering the conductor layer located on the upper main surface of the uppermost insulator layer and a protective layer covering the conductor layer located on the lower main surface of the lowermost insulator layer. The protective layer prevents the conductor layer from being exposed from the multilayer body 12. However, a configuration in which a portion of a conductor is exposed from the protective layer is possible. The material of the protective layer is an insulating material different from that of the insulator layers 16a to 16f.

The other direction (downward direction) of the up-down direction may be the first direction, and the one direction (the upward direction) of the up-down direction may be the second direction.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer board comprising:
a multilayer body including a first insulator layer, a second insulator layer, and a third insulator layer laminated in this order in an up-down direction, a first region in which the first insulator layer, the second insulator layer, and the third insulator layer are located when viewed in the up-down direction and a second region in which the first insulator layer and the third insulator layer are located and the second insulator layer is not located when viewed in the up-down direction, each of the first insulator layer and the third insulator layer including a first main surface located in the up-down direction and a second main surface located in the up-down direction;
a plurality of interlayer connection conductors in the multilayer body;
a conductor in or on the first insulator layer; and
a first conductor layer located on the second main surface of the third insulator layer; wherein
the plurality of interlayer connection conductors include one or more first interlayer connection conductors located in the first region and passing through any of the first insulator layer, the second insulator layer, and the third insulator layer in the up-down direction and a second interlayer connection conductor located in the second region and passing through the third insulator layer in the up-down direction;
the second interlayer connection conductor is joined to the conductor and the first conductor layer; and
an area of the second interlayer connection conductor viewed in the up-down direction is larger than a minimum value of areas of the one or more first interlayer connection conductors viewed in the up-down direction.

2. The multilayer board according to claim 1, wherein
the one or more first interlayer connection conductors include one or more third interlayer connection conductors passing through the third insulator layer in the up-down direction; and
the area of the second interlayer connection conductor viewed in the up-down direction is larger than an area of each of the one or more third interlayer connection conductors viewed in the up-down direction.

3. The multilayer board according to claim 1, wherein the area of the second interlayer connection conductor viewed in the up-down direction is larger than a maximum value of the areas of the one or more first interlayer connection conductors viewed in the up-down direction.

4. The multilayer board according to claim 1, wherein the conductor is a second conductor layer located on the second main surface of the first insulator layer.

5. The multilayer board according to claim 4, wherein
the second conductor layer includes a third main surface located in the up-down direction and a fourth main surface located in the up-down direction; and
a surface roughness of the third main surface of the second conductor layer is larger than a surface roughness of the fourth main surface of the second conductor layer.

6. The multilayer board according to claim 4, wherein
the plurality of interlayer connection conductors include a fourth interlayer connection conductor located in the second region and passing through the first insulator layer in the up-down direction;
the fourth interlayer connection conductor is joined to the second conductor layer; and
the area of the second interlayer connection conductor viewed in the up-down direction is larger than an area of the fourth interlayer connection conductor viewed in the up-down direction.

7. The multilayer board according to claim 1, wherein
the first conductor layer has a linear shape when viewed in the up-down direction; and
a line width of the first conductor layer viewed in the up-down direction in the first region is larger than a line width of the first conductor layer viewed in the up-down direction in the second region.

8. The multilayer board according to claim 7, wherein
the multilayer body includes a boundary region including a boundary between the first region and the second region;
a thickness of the multilayer body in the up-down direction in the first region is larger than a thickness of the multilayer body in the up-down direction in the second region;
a thickness of the multilayer body in the up-down direction in the boundary region decreases in a direction from the first region to the second region; and
a line width of the first conductor layer viewed in the up-down direction in the boundary region decreases in the direction from the first region to the second region.

9. The multilayer board according to claim 1, wherein the conductor is a fourth interlayer connection conductor located in the second region and passing through the first insulator layer in the up-down direction.

10. The multilayer board according to claim 9, wherein the area of the second interlayer connection conductor viewed in the up-down direction is larger than an area of the fourth interlayer connection conductor viewed in the up-down direction.

11. The multilayer board according to claim 1, wherein
the first conductor layer includes a third main surface located in the up-down direction and a fourth main surface located in the up-down direction; and
a surface roughness of the third main surface of the first conductor layer is larger than a surface roughness of the fourth main surface of the first conductor layer.

12. The multilayer board according to claim 1, wherein
the multilayer body includes a fourth insulator layer; wherein
the fourth insulator layer, the first insulator layer, the second insulator layer, and the third insulator layer laminated in this order in the up-down direction; and
the fourth insulator layer is located in the first region and is not in contact with a boundary between the first region and the second region.

13. The multilayer board according to claim 1, wherein
the multilayer body includes a fifth insulator layer, a fourth insulator layer, the first insulator layer, the second insulator layer, and the third insulator layer laminated in this order in the up-down direction;
the fifth insulator layer is located in the first region and the second region; and
the fourth insulator layer is located in the first region and is not in contact with a boundary between the first region and the second region.

14. The multilayer board according to claim 1, wherein a thickness of the second insulator layer in the up-down direction decreases toward a boundary between the first region and the second region.

15. The multilayer board according to claim 14, wherein
a thickness of the first insulator layer in the up-down direction at the boundary between the first region and the second region is larger than a thickness of the first insulator layer in the up-down direction in the first region; and
a thickness of the third insulator layer in the up-down direction at the boundary between the first region and the second region is larger than a thickness of the third insulator layer in the up-down direction in the first region.

16. The multilayer board according to claim 1, wherein a material of the one or more first interlayer connection conductors is of a same kind as a material of the second interlayer connection conductor.

17. The multilayer board according to claim 1, wherein a material of the first insulator layer, a material of the second insulator layer, and a material of the third insulator layer are a same thermoplastic resin.

18. The multilayer board according to claim 17, wherein the thermoplastic resin includes a liquid crystal polymer or polytetrafluoroethylene.

19. The multilayer board according to claim 1, wherein the multilayer board is made of a flexible material.

20. The multilayer board according to claim 1, wherein the first, second, and third insulator layers are fusion-bonded.
